(19) United States
(12) Patent Application Publication
(10) Pub. No.: US 2015/0295115 A1
(43) Pub. Date: Oct. 15, 2015

(54) INFRARED PHOTOVOLTAIC DEVICE AND MANUFACTURING METHOD

(71) Applicants: Jose Briceno, Tokyo-to (JP); Koji MATSUMARU, Nigata-ken (JP)

(72) Inventors: Jose Briceno, Tokyo-to (JP); Koji MATSUMARU, Nigata-ken (JP)

(21) Appl. No.: 14/216,540

(22) Filed: Mar. 17, 2014

Related U.S. Application Data
(63) Continuation-in-part of application No. 13/844,686, filed on Mar. 15, 2013.
Application No. 13/844,686 is a continuation-in-part of application No. 13/844,428, filed on Mar. 15, 2013.
Application No. 13/844,428 is a continuation-in-part of application No. 13/844,298, filed on Mar. 15, 2013, now Pat. No. 8,952,246.
Application No. 13/844,298 is a continuation-in-part of application No. 13/844,521, filed on Mar. 15, 2013, now Pat. No. 9,099,578.
Application No. 13/844,521 is a continuation-in-part of application No. 13/844,747, filed on Mar. 15, 2013.
(60) Provisional application No. 61/801,244, filed on Mar. 15, 2013.
(60) Provisional application No. 61/800,800, filed on Mar. 15, 2013.
(60) Provisional application No. 61/800,912, filed on Mar. 15, 2013.
(60) Provisional application No. 61/801,019, filed on Mar. 15, 2013.
(60) Provisional application No. 61/801,145, filed on Mar. 15, 2013.
(60) Provisional application No. 61/761,342, filed on Feb. 6, 2013.
(60) Provisional application No. 61/722,693, filed on Nov. 5, 2012.
(60) Provisional application No. 61/715,283, filed on Oct. 17, 2012.
(60) Provisional application No. 61/715,286, filed on Oct. 18, 2012.
(60) Provisional application No. 61/715,287, filed on Oct. 18, 2012.
(60) Provisional application No. 61/619,410, filed on Apr. 2, 2012.
(60) Provisional application No. 61/655,449, filed on Jun. 4, 2012.
(60) Provisional application No. 61/738,375, filed on Dec. 17, 2012.

(51) Int. Cl. H01L 31/07; H01L 31/18; H01L 31/0232; H01L 31/0224; H01L 31/0216

(52) U.S. Cl. CPC H01L 31/07; H01L 31/022483; H01L 31/022441; H01L 31/02168; H01L 31/02327; H01L 31/1884

(57) ABSTRACT

A hybrid photovoltaic (PV) device is composed of a first electrode layer, a semiconductor substrate, a semiconductor PV layer, and a bottom electrode that forms a Shottcky junction between said bottom metal electrode and the PV layer. Because of existence of the Shottcky junction, the PV cell permits light to electricity conversion over a wide-range of light wavelengths, from the so-called visible light (between 350 nm to 900 nm wavelength) to the infrared light (over 900 nm wavelength). Also described is a method for manufacturing a hybrid PV device. The method of manufacturing comprises performing the steps of cleaning a semiconductor substrate; introducing an inert gas under vacuum and a high temperature to form a semiconductor PV layer having a high resistivity on a first side of the substrate; forming a metal bottom layer on the semiconductor PV layer to create a Shottcky junction between the metal layer and said semiconductor PV layer; and forming a transparent electrode layer on the second side of said substrate. In a second embodiment, an n+ layer is formed between the semiconductor substrate and the transparent electrode layer to improve ohmic contact between these two layers.

### CROSS-REFERENCE TO RELATED APPLICATIONS

This application claims the benefit of U.S. application Ser. No. 13/844,686, filed Mar. 15, 2013 (Attorney Docket No. 44671-047 (P7)); U.S. Provisional Application No. 61/761,342, filed Feb. 6, 2013 (Attorney Docket No. 446714-047 (P7)); U.S. application Ser. No. 13/844,298, filed Mar. 15, 2013 (Attorney Docket No. 44671-033 (P2)); U.S. Provisional Application No. 61/619,410, filed Apr. 2, 2012 (Attorney Docket No. 44671-033 (P2)); U.S. application Ser. No. 13/844,428, filed Mar. 15, 2013 (Attorney Docket No. 44671-034 (P3)); U.S. Provisional Application No. 61/722,693, filed Nov. 5, 2012 (Attorney Docket No. 44671-034 (P3)); U.S. application Ser. No. 13/844,521, filed Mar. 15, 2013 (Attorney Docket No. 44671-035 (P4)); U.S. Provisional Application No. 61/655,449, filed Jun. 4, 2012 (Attorney Docket No. 44671-035 (P4)); U.S. application Ser. No. 13/844,747, filed Mar. 15, 2013 (Attorney Docket No. 44671-038 (P5)); U.S. Provisional Application No. 61/738,375, filed Dec. 17, 2012 (Attorney Docket No. 44671-038 (P5)); U.S. Provisional Application No. 61/715,283, filed Oct. 17, 2012 (Attorney Docket No. 44671-041 (P12)); U.S. Provisional Application No. 61/715,286, filed Oct. 18, 2012 (Attorney Docket No. 44671-043 (P13)); U.S. Provisional Application No. 61/715,287, filed Oct. 18, 2012 (Attorney Docket No. 44671-044 (P14)); U.S. Provisional Application No. 61/801,019, entitled Manufacturing Equipment for Photovoltaic Devices, filed 15 Mar. 2013 (Attorney Docket No. 44671-050 (P32)); U.S. Provisional Application No. 61/800,912, entitled infrared Photovoltaic Device, filed 15 Mar. 2013 (Attorney Docket No. 44671-049 (P10)); U.S. Provisional Application No. 61/800,800, entitled Hybrid Transparent Electrode Assembly for Photovoltaic Cell Manufacturing, filed 15 Mar. 2013 (Attorney Docket No. 44671-048 (P23)); U.S. Provisional Application No. 61/801,145, entitled PIN Photo-voltaic device and Manufacturing Method, filed 15 Mar. 2013 (Attorney Docket No. 44671-051 (P17)), and U.S. Provisional Application No. 61/801,244, entitled Infrared Photo-voltaic device and Manufacturing Method, filed 15 Mar. 2013 (Attorney Docket No. 44671-052 (P36)), the entireties of which are incorporated by reference as if fully set forth herein.

This invention relates to copending U.S. patent application Ser. No. 13/844,686, filed 15 Mar. 2013 (docket number P7, sub case 003); the entirety of which is incorporated by reference as if fully set forth herein.

### FIELD OF THE INVENTION

The present invention relates to photovoltaic devices, and in particular, an infrared photovoltaic device structure with improved photovoltaic properties and a simplified method of manufacture.

### BACKGROUND OF THE INVENTION

A solar cell (also called a photovoltaic cell) is an electrical device that converts the energy of light directly into electricity by the photovoltaic effect. Prior art solar cell technology typically utilizes crystalline silicon as a main ingredient, and in some other cases, inexpensive poly-crystalline silicon or other compound semiconductors. In addition, other technologies use organic materials for the so-called dye-sensitized solar cells. Prior art crystalline silicon solar cells are often fabricated by forming a high concentration n-type layer on a p-type silicon substrate. This high concentration n-type layer is generally formed by a process of ion implantation, or diffusion, introducing the n-type dopant phosphorous, to form a PN junction, followed by an annealing process. Once the PN junction is so formed, anode and cathode electrodes are formed to complete the photovoltaic cell.

Recently, the introduction of an intrinsic layer between the P and N layers to create a so-called PIN junction cell has also been introduced, to increase cell efficiency. However, in the same manner as the PN junction solar cell, the manufacturing process for PIN junction cells is based on impurity doping methods that are expensive and use toxic materials. It is highly desirable to have a manufacturing process for photovoltaic materials that reduces or eliminates toxic additives.

The conventional methods for manufacturing photovoltaic materials also require a multi-step process, or different processes, with each step possibly taking place at a different apparatus and at different times, and requiring its own management and resources. It is highly desirable to have a manufacturing process for photovoltaic (PV) materials that reduces the number of necessary processes or steps to reduce costs.

Currently available photovoltaic technology generally provides electric energy converted from sunlight only during the day. In addition, these legacy PV cells show best performance when the sun is high in the sky, and cell efficiency or performance drops drastically during morning and evening hours, as well as during overcast days. During cloudy or overcast days, the amount of energy that reaches solar cells is limited, since light is filtered by the cloud cover, therefore reducing the total amount of electric power generated by such solar cells in these conditions.

However, since prior art silicon-based PV cells are unable to produce electricity capturing infrared light, the performance of such cells will drop considerable in bad weather, despite the fact that the amount of infrared light (over 900 nm wavelength) reaching the earth's surface is practically unaffected by the weather or the amount of cloud cover. To overcome this issue, there are some prior art PV technologies able to capture infrared light, but using very expensive and toxic materials such as arsenic (As). It is highly desirable to have a manufacturing process for photovoltaic cell design that permits light to electricity conversion of a wide-range of light wavelengths, from the so-called visible light range to the infrared light range.

### BRIEF SUMMARY OF THE INVENTION

Preferred embodiments of the present invention provide a hybrid PV solar cell, one that generates electricity from both visible and infrared light (also called the infrared PV cell below), and a method of manufacturing the cell. The method of manufacturing the PV device is preferably a toxic material free process, which lowers the overall manufacturing cost.

The infrared PV solar cell is composed of a first electrode layer, a semiconductor substrate, a semiconductor PV layer, and a bottom electrode that forms a Shottcky junction between said bottom metal electrode and the PV layer.

Because of existence of the Shottcky junction, the PV cell of the present invention permits light to electricity conversion over a wide-range of light wavelengths, from the so-called visible light (between 350 nm to 900 nm wavelength) to the infrared light (over 900 nm wavelength). The PV structure only absorbs energy within the visible light spectrum, while the semiconductor/metal Shottcky interface absorbs energy in the infrared light wavelength or higher.

The method of manufacturing a photovoltaic (PV) device having a semiconductor substrate comprises performing the steps of: cleaning said substrate; introducing an inert gas under vacuum and a high temperature to form a semiconductor PV layer having a high resistivity on a first side of the substrate; forming a metal bottom layer on said semiconductor PV layer to create a Shottcky junction between the metal layer and said semiconductor PV layer; and forming a transparent electrode layer on the second side of said substrate.

### Problems Addressed by the Current Invention

In order to maximize the semiconductor/metal Shottcky contact surface area and therefore the infrared spectrum cell performance, the Shottcky interface was placed in the bottom of the cell. The top of the cell includes a transparent electrode. Both of these top and bottom layers are shown in FIG. 1 and FIG. 2.

It is critical that the semiconductor substrate must be as thin a possible, in order to maximize the amount of light that penetrates into the wafer substrate and subsequently be absorbed by the bottom PV layer, and the Shottcky interface respectively.

### BRIEF DESCRIPTION OF THE DRAWINGS

Preferred embodiments of the present invention are illustrated by way of example, and not by way of limitation, in the figures of the accompanying drawings and in which like reference numerals refer to similar elements and in which:

FIG. 1 is a cross-sectional view of an infrared PV device during one stage of manufacture according to one embodiment after the PV device has been formed.

FIG. 2A is a cross-sectional view of another infrared PV device 100 and FIG. 2B is a partial circuit diagram 120 showing the equivalent circuit elements formed by semiconductor bulk layer, the PV structure and the bottom metal layer according to one embodiment of the present invention.

FIG. 3 is a flow diagram illustrating an example of the steps for manufacturing the PV device 100 shown in FIG. 2.

FIG. 4 is a cross-sectional view of an infrared PV device 300 during one stage of manufacture according to yet another embodiment after the PV device has been formed.

FIG. 5 is a flow diagram illustrating an example of the steps for manufacturing the PV device 300 shown in FIG. 4.

FIG. 6 is a cross-sectional view of an infrared PV device 500 during one stage of manufacture according to another embodiment after the PV device has been formed.

FIG. 7 is a flow diagram illustrating an example of the steps for manufacturing the PV device 500 and shown in FIG. 6.

### DETAILED DESCRIPTION OF PREFERRED EMBODIMENTS OF THE INVENTION

In the following description, numerous specific details have been set forth to provide a more thorough understanding of embodiments of the present invention. It will be appreciated however, by one skilled in the art, that embodiments of the invention may be practiced without such specific details or with different implementations for such details. Additionally some well-known structures have not been shown in detail to avoid unnecessarily obscuring the present invention.

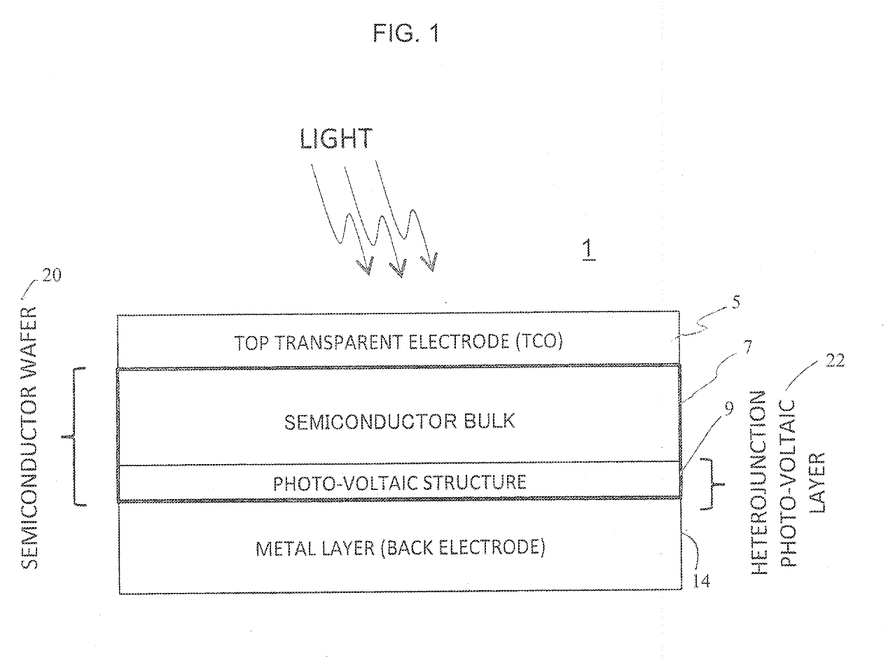

FIG. 1 is a cross-sectional view of infrared PV cell 1 during one stage of the manufacturing process according to one embodiment of the present invention. Device 1 includes a first electrode layer 5, which is top transparent (TCO) electrode to allow light to penetrate into the hybrid PV cell. Electrode layer 5 is typically made of a transparent conductive oxide (TCO). The TCO layer 5 is formed on a semiconductor bulk layer 7. The layer may be formed by any means known in the art including impurity diffusion or doping of the semiconductor substrate 7. PV structure 9, also called semiconductor PV layer 9, is formed upon heat treatment of semiconductor bulk layer 7 resulting in semiconductor wafer 20. Finally, a bottom or back surface electrode 14 is deposited on the bottom surface of PV structure 9. Back or bottom electrode 14 is composed of a metal layer. In combination with PV structure 9, a Shottcky junction or heterojunction PV layer 22 is formed. This layer 22 is a hybrid design that enables PV cell 1 to transform both visible light and infrared light simultaneously into electricity.

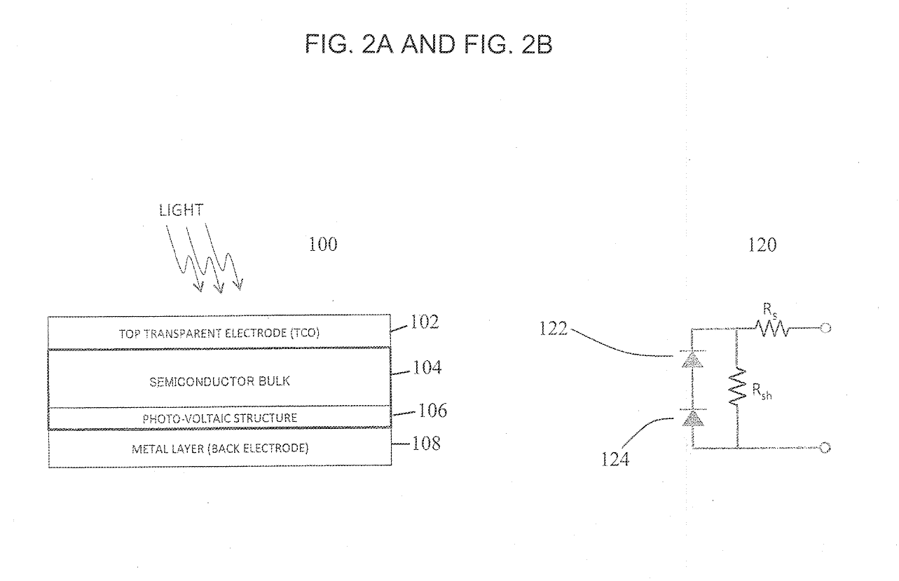

As seen in FIG. 2, the hybrid PV cell 100 of the present invention comprises two main components. A semiconductor photovoltaic layer that has silicon material having a resistivity different from that of the silicon semiconductor substrate, and a metal-semiconductor Schottky junction as discussed above. Referring to FIG. 2B, a partial circuit diagram 120 is shown which illustrates the equivalent circuit elements formed by the semiconductor bulk layer 104, the PV structure 106, and the metal layer 108. As is seen, the junction between the semiconductor bulk layer 104 and the PV structure 9 creates a first equivalent diode 122, and the Shottcky junction between the PV structure 9 and metal layer 108 creates a second equivalent diode 124. This metal layer 108 also functions as the back or bottom electrode of PV cell 100. As illustrated in FIG. 2B, both photo-voltaic joints 122 and 124 are aligned so the joints compensate each other, improving overall cell performance, in addition to achieving infrared light PV capabilities.

The junction between the semiconductor and PV structure layers reacts to the visible-light spectrum, while the Schottky junction between the metal and PV structure layers reacts to the infrared light spectrum. These two combined junctions make a very powerful hybrid solar cell, capable of producing electricity from light of a very wide spectrum, from the visible through the infrared wavelengths.

A transparent top electrode is fabricated on top of the cell 100, allowing light to penetrate both photo-voltaic junctions. The metal layer 108 also functions as the bottom or back. ohmic electrode located at the bottom of cell 100.

Table 1 below describes the main parameters of the materials used to fabricate the photo-voltaic cell in the present invention.

TABLE 1

| Parameter | Value | Typical Case |
|---|---|---|
| Top electrode | TCO: | ZnO |
| | ZnO, ITO, AZO, GZO, | 150 nm in thickness |
| | IZO, and NbO₂. | |
| | It is crucial to use a | |
| | material and thickness | |
| | that will allow visible | |
| | light and infrared light | |
| | to penetrate | |
| Semiconductor | Silicon | N-type crystalline silicon |
| bulk | semiconductor | Orientation (100) |
| Wafer | <300 μm | Preferable <200 μm |
| thickness | | in thickness |
| Metal | Single or multi | Single Layer: Au, about |
| layer/back | metal layer | 200 nm |
| electrode | Au, Pt, W, Ni, | Multi-metal layer: |
| | Fe, Pd, Ag | Inner layer (interface with |
| | | silicon): Au, About 100 |
| | | nm in thickness |
| | | Outer layer: Ag By screen |
| | | printing |

### Fabrication Process

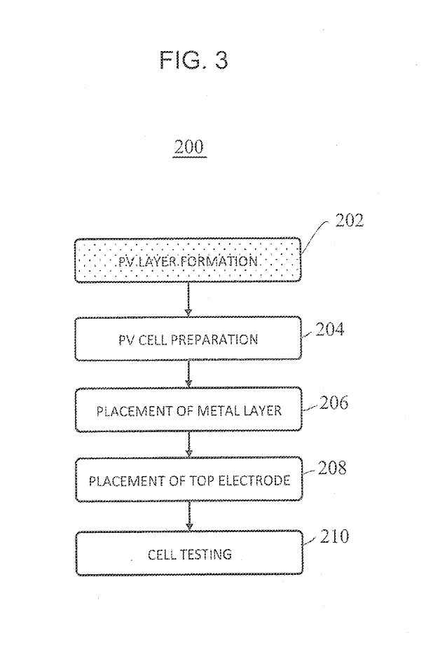

One embodiment of the present invention to fabricate a hybrid PV cell 100 as shown in FIG. 2 uses a process 200 as depicted in the flow diagram of FIG. 3, which shows the following sequential steps:

First, a wafer heating process is used at step 202 to form the PV structure 9 on the semiconductor bulk layer 104.

Next is a PV cell preparation step 204, in which a neutral detergent is used in a wafer cleaning step and an organic neutral detergent is used for abrading agent removal.

Metal layer 206 is then formed, in which metal layer 108 is typically formed by sputtering.

Placement of top electrode step 208 is then performed, in which electrode TCO 102 is typically deposited by sputtering. This step is followed by the optional steps of applying a silver paste bus-bar on top of electrode 102 by screen printing and an anti-reflection coat on top of the bus-bar also by screen printing to complete the fabrication process.

Cell testing is performed at step 210, in which the PV device is run through a series of tests to determine its overall efficiency.

In other words, once the photo-voltaic layer in the semiconductor substrate is fabricated, a metal layer is placed on top of the PV layer. This metal layer functions as both the metal-semiconductor Shottcky junction as well as the photo-voltaic cell back electrode. The transparent conductive oxide layer is placed on top of the cell to complete the fabrication process.

### BEST MODE FOR CARRYING OUT THE INVENTION

### EXAMPLE 1

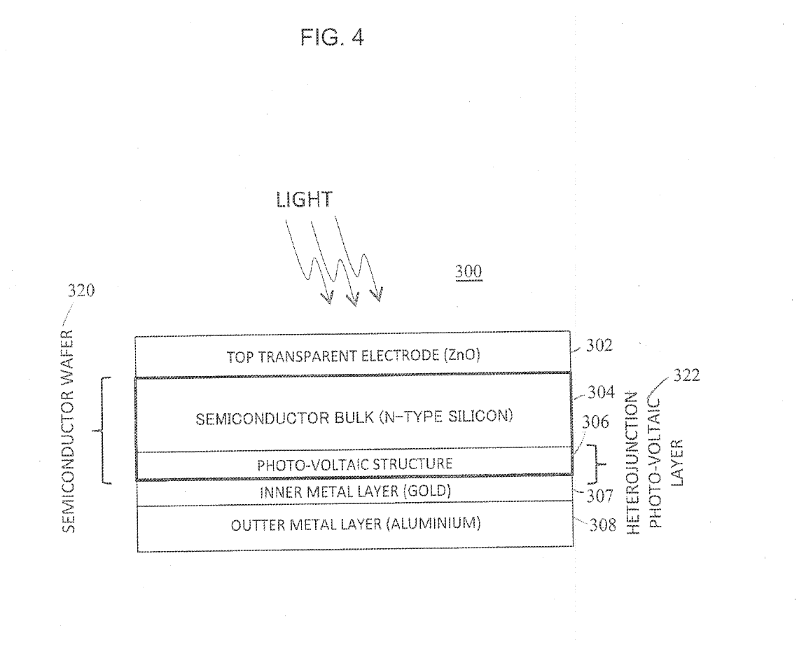

FIG. 4 is a cross-sectional view of an infrared PV device 300 during one stage of manufacture according to yet another embodiment of the invention. PV cell 300 includes a top transparent (TCO) electrode 302. The TCO layer 302 is formed on a semiconductor bulk layer 304, which is preferably an n-type silicon single crystal wafer substrate. A PV structure 306 is formed on semiconductor bulk layer 304 after heat treatment to result in a semiconductor wafer 320. An inner metal layer preferably of gold 307 is deposited on the bottom surface of PV structure 306. The junctions formed by the junction between the semiconductor layer 304 and the PV structure 306 and the Schottky junction formed by the junction between the PV structure 306 and the metal layer 307 form heterojunction PV layer 322. Finally, an outer metal layer of aluminum 308 is preferably formed on the bottom of the inner metal gold layer 307.

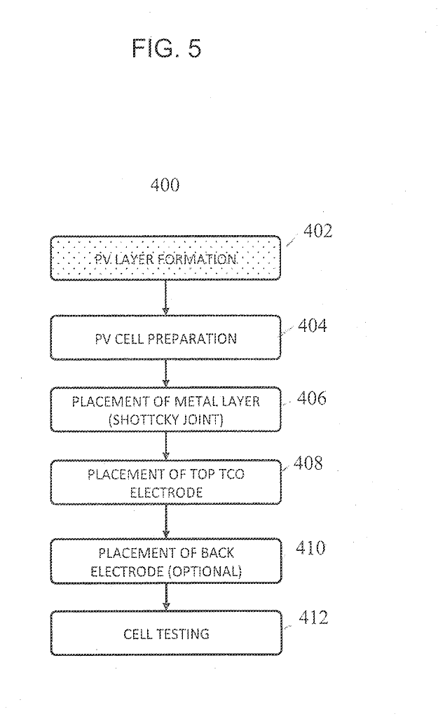

FIG. 5 is a flow diagram illustrating an example of the steps 400 for manufacturing the PV device 300 shown in FIG. 4. The process shown in FIG. 5 begins with formation of the PV structure 306 at step 402. The semiconductor bulk layer is cleaned at step 404, at step 406, metal layer 307 is added to form a Shottcky junction, the top TCO electrode 302 is placed on the opposite sureface of the semiconductor bulk layer 304 at step 408. These are all substantially the same as steps 202, 204, 206, 208 of FIG. 3 with the difference being that gold is specified as the metal layer that is deposited to a preferred thickness of 200 nm by sputtering in step 406 and ZnO is specified as the TCO in step 408. In addition, an optional second metal layer 308 is formed on top of metal layer 307, as seen at step 410. This layer is preferably formed by screen printing of aluminum paste followed by firing.

More specifically, a 6-inch n-type silicon single crystal substrate having a resistivity of 1 to 5 (Ω cm), (100) crystal orientation is first cleaned by the use of a typical RCA cleaning method.

The substrate cleaning is performed in the following steps: removing organic material using sulfuric acid-hydrogen peroxide water cleaning for ten minutes at 350 K; pure water cleaning followed by nitrogen blow drying with infrared and ultraviolet light drying; cleaning using a 0.5% hydrofluoric acid solution; cleaning by ammonium-hydrogen peroxide water at 350 K for 10 minutes; removing heavy metal contamination by 80° C. hydrochloric acid-hydrogen peroxide water cleaning for ten minutes after pure water rinsing; and, lastly, pure water cleaning and nitrogen gas drying followed by paper IPA drying.

Next, a high resistivity layer, which is a first layer of the photo-voltaic generation layer, is preferably formed by the following method.

Inert gas is introduced into a quartz boat containing the semiconductor bulk wafer 304, which had been previously vacuumed to approximately 1 E-3 Pa. The quartz boat is then heated and kept at pre-determined annealing temperature (800K or more) for 30 minutes.

While vacuum of approximately 1 E-3 Pa was used in the present example, the degree of the vacuum may not be specified in particular at a vacuum of approximately 20 Pa or lower. Further, while argon gas was used as the inert gas in the present example, another inert gas such as helium gas and the like or a mixture of these inert gases may be used.

A variety of heating methods can be used to form intrinsic silicon layer 9, including but not limited to infrared heating, laser heating, and hot-wall furnace heating. In some embodiments, the particular heating methods used for treating the substrate layer have an effect on photovoltaic performance of the photovoltaic cell. In some embodiments, the cooling rate after the heating stage is a crucial factor to photovoltaic cell fabrication, whereas the heating rate is a less crucial factor to photovoltaic cell fabrication. Maximum photovoltaic cell performance can be obtained at heating temperatures above 1500° K, at heating times above 5 minutes, at approximately 1×10⁻³ Pa. The overall parameters used during heating step include temperatures ranging from 852 1700° Kelvin, heating times from one to 600 min., atmospheres from vacuum, argon, nitrogen or other inert gas at temperatures up to 1 atm. After the heating process is completed, the substrate is transformed into a photovoltaic semiconductor material having a high-resistivity layer therein.

Next, the substrate is preferably cleaned by the use of a typical RCA cleaning method, similar to the one mentioned above.

A 100 nm layer of gold is then formed on the PV structure by means of a sputtering method. While a sputtering method was used in this example, any other method may be utilized to fabricate the thin metal layer on top of the semiconductor photo-voltaic layer. While the thickness of 100 nm is used in the present example, the thickness is not limited to 100 nm, as long as it is sufficiently thick enough to block light, i.e., to reflect all light back to the cell.

Next, a 150 nm thick ZnO transparent conductive film is formed over the opposite side of the silicon substrate by a sputtering method.

An optional silver paste bus-bar is formed on top of the ZnO layer to improve overall top electrode electrical properties. Placement of the bus-bar is preferably performed by screen printing method.

While ZnO was used in the present example, another transparent conductive film such as ITO, SnO2, FTO, AZO, GZO, IZO, TNO, ATO, FeO2, and NbO2, or a stacked structure thereof may be used, and the transparent conductive film may be formed by PLD, MOCVD, a coating method, or the like, and not limited to the sputtering method.

Next, a silicon nitride film is preferably formed consecutively as an anti-reflection film. Lastly, a metal layer of aluminum is preferably added on top of the gold layer. This second metal layer is added by screen printing on the surface of the gold layer and heating of the second layer at 550 K to remove the binder, and complete the solar cell construction.

While, a single crystal silicon having 1 to 5 (Ω-cm) and orientation (100) is used for the silicon substrate in the present example, the face orientation may be (110) or (111), and solar grade silicon or poly-crystalline silicon may be used. When a silicon substrate having a different resistivity is used, it is necessary to change heating temperature and time.

While a gold metal layer is used in the present example, any metal having a work function greater than that of n-type silicon semiconductor may be used, such as platinum (Pt), tungsten (W), nickel (Ni), iron (Fe), and palladium (Pd).

### EXAMPLE 2

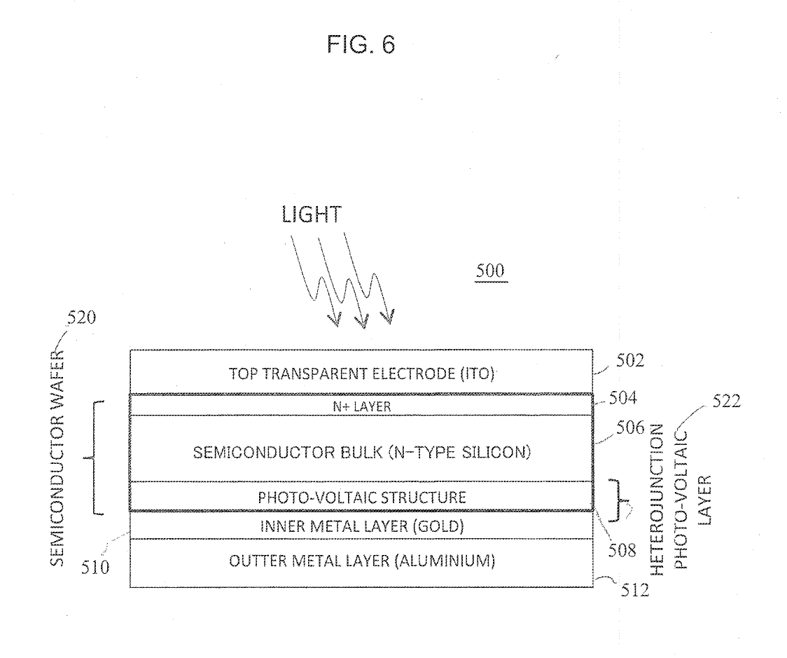

Example 2 was carried out to fabricate an infrared PV cell 500 as shown in FIG. 6. FIG. 6 is a cross-sectional view of an infrared PV device 500 during one stage of manufacture according to another embodiment after the PV device has been formed. In this example, top transparent (TCO) electrode 502 is deposited on an n+ silicon layer 504 which was deposited on semiconductor bulk layer 506. As in the prior embodiments, PV structure 508 is deposited on semiconductor bulk 506 to form the semiconductor wafer 520 and an inner metal layer of gold 510 is deposited on the bottom surface of PV structure 508. Finally, an outer metal layer of aluminum 512 is deposited on the bottom of the inner metal gold layer 510. As described above the junctions between semiconductor bulk layer 506, PV structure 508, and gold layer 510 create heterojunction PC layer 522.

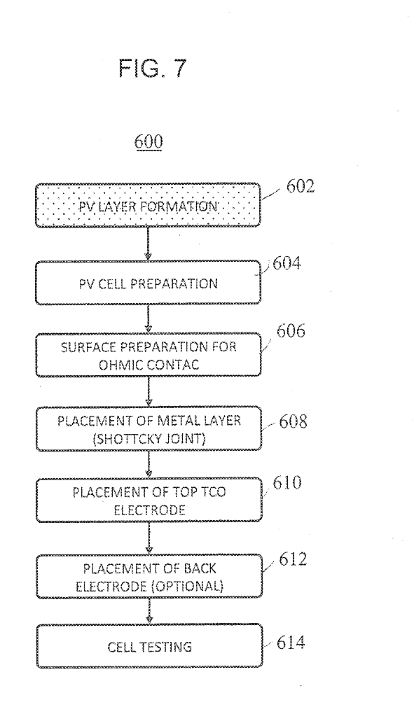

FIG. 7 is a flow diagram illustrating an example of the steps 600 for manufacturing the PV device 500 shown in FIG. 6. FIG. 7 shows the following sequential steps. The process 600 begins with formation of the PV structure 508 at step 602. PC cell wafer cleaning at step 604, placement of metal layer step at 608 to form a Shottcky junction, placement of top TCO electrode step 610, and placement of back electrode step (optional) 612. Cell testing is performed at step 614 once the PV device has been constructed.

Note that all of the steps followed in example 2 are substantially the same as steps 402, 404, 406, 408, 410 and 412 of FIG. 5 and a detailed description of example 1 above except for step 606 in FIG. 7. In step 606, an n+ silicon plus layer 504 is deposited between the TCO layer 502 and the silicon semiconductor bulk substrate 506. In addition, a silver paste bus-bar is optionally deposited on the TCO layer before or after the anti-reflection film is also optionally deposited on the TCO layer. This optional silver paste bus-bar is added to improve overall top electrode electrical properties. Placement of the bus-bar is performed by screen printing method.

The foregoing description of preferred embodiments of the present invention has been provided for the purposes of illustration and description. It is not intended to be exhaustive or to limit the invention to the precise forms disclosed. Various additions, deletions and modifications are contemplated as being within its scope. The scope of the invention is, therefore, indicated by the appended claims rather than the foregoing description. Further, all changes which may fall within the meaning and range of equivalency of the claims and elements and features thereof are to be embraced within their scope.

We claim:

1. An infrared photovoltaic device comprising a semiconductor substrate, a first electrode layer on one side of said substrate, a semiconductor photovoltaic (PV) layer on the opposite side of said substrate, and a metal bottom electrode that forms a Shottcky junction between said bottom metal electrode and said PV layer.

2. The device of claim 1 wherein said first electrode layer is a transparent conductive oxide (TCO).

3. The device of claim 1 wherein said TCO is selected from the group consisting of ZnO, ITO, ACO, GZO, MO, and NbO2.

4. The device of claim 3 wherein said TCO is ZnO.

5. The device of claim 1 wherein said semiconductor substrate is an n-type silicon single crystal substrate, and wherein said n-type silicon substrate has a resistivity in the range of about 1 to about five ohm·centimeter (Ω·cm).

6. The device of claim 1 further comprising an n+ layer between said semiconductor substrate and said first electrode layer.

7. The device of claim 1 wherein said bottom electrode is a metal selected from the group consisting of gold, platinum, tungsten, nickel, iron, palladium and mixtures thereof.

8. The device of claim 7 wherein said bottom electrode is gold.

9. The device of claim 8 wherein said bottom electrode is formed at a thickness sufficient to reflect all incident light.

10. The device of claim 7 further comprising a second metal layer on said bottom electrode, in which said second metal layer is aluminum.

11. The device of claim 1 further comprising a silver paste bus-bar on top of said first electrode layer and an anti-reflective coating on top of said silver paste bus bar.

12. A method of manufacturing a photovoltaic (PV) device having a semiconductor substrate comprising performing the steps of said substrate; introducing an inert gas under vacuum and a high temperature to form a semiconductor PV layer having a high resistivity on a first side of the substrate; forming a metal bottom layer on said semiconductor PV layer to create a Shottcky junction between the metal layer and said semiconductor PV layer; and forming a transparent electrode layer on the second side of said substrate.

13. The method of claim 12 wherein said substrate is an n-type silicon single crystal substrate having a resistivity the range of about 1 to about five ohm·centimeter (Ω·cm).

14. The method of claim 12 wherein said semiconductor PV layer has a thickness of at least 100 nanometers (nm).

15. The method of claim 12 further comprising forming an anti-reflective coating on the top of said transparent electrode layer, wherein said anti-reflective coating is silicon nitride.

16. The method of claim 12 wherein said transparent electrode layer is a transparent conductive oxide (TCO) film selected from the group consisting of ZnO, ITO ACO, OZO, IZO, and NbO2.

17. The method of claim 12 wherein said TCO film is ZnO.

18. The method of claim 12 wherein said bottom metal layer is gold having a thickness sufficient to reflect all incident light.

19. The method of claim 12 wherein said bottom metal layer is a metal selected from the group consisting of gold, platinum, tungsten, nickel, iron, palladium and mixtures thereof.

20. The method of claim 19 wherein a second metal layer is deposited over the bottom metal layer, wherein said second metal layer is aluminum.

21. The method of claim 12 further comprising ion implanting a material into the surface of the second side of said substrate before forming said transparent electrode layer.

22. The method of claim 21 wherein the ion material used for the ion implantation is selected from the group consisting of phosphorus ions or arsenic ions.
